(19) United States
(12) Patent Application Publication
(10) Pub. No.: US 2019/0198203 A1
(43) Pub. Date: Jun. 27, 2019

(54) SURFACE-MOUNTABLE THIN FILM RESISTOR NETWORK

(71) Applicant: KOA CORPORATION, Ina-shi, Nagano (JP)

(72) Inventors: Satoshi Kanegae, Ina-shi (JP); Tomonori Oguchi, Ina-shi (JP); Noboru Kashiwagi, Ina-shi (JP)

(73) Assignee: KOA CORPORATION, Ina-shi, Nagano (JP)

(21) Appl. No.: 16/311,858

(22) PCT Filed: Jun. 2, 2017
(86) PCT No.: PCT/JP2017/020591

§ 371 Date: Dec. 20, 2018

(30) Foreign Application Priority Data
Jun. 27, 2016 (JP) 2016-126651

(51) Int. Cl. H01C 13/02; H01C 17/00; H01C 1/034; H01C 1/01; H01L 23/495; H01L 23/31

(52) U.S. Cl. CPC H01C 13/02; H01C 17/006; H01C 1/034; H01L 23/3107; H01L 23/49541; H01L 23/4952; H01C 1/01

(57) ABSTRACT

Provided is a surface-mountable thin film resistor network, which includes a chip, on which a thin film resistor network integrated array is formed, and a molded resin package, which encapsulate the chip. The surface-mountable thin film resistor network is provided with a chip (13) on which a thin film resistor integrated array has been formed; an island (12) on which the chip is fixed; a plurality of lead terminals (14) extending outward around periphery of the island; wires (15) connecting electrodes of resistors mounted on the chip to the lead terminals; and a molded resin package (20) that encapsulate a portion, which includes the wires; wherein a hanging lead (18) extending from the island is cut at an end surface of the molded resin package, and an electrical insulation (21) is applied to the cut section of the hanging lead.

### TECHNICAL FIELD

The invention relates to electronic parts, especially relating to surface-mountable thin film resistor networks.

### BACKGROUND ART

Japanese laid open patent publication 2012-60105 discloses a semiconductor device, which is encapsulated in a molded resin body. A lead frame includes an, island, a hanging lead connecting the island to the outer frame, and a plural of lead terminals connected to the outer flame. A chip is fixed on the island, and the chip is connected to the lead terminals by wire bonding. These are encapsulated into a molded resin body, and unnecessary outer frame portion etc. are cut away to form the semiconductor device encapsulated in the molded resin body.

In these semiconductor devices, the hanging lead connecting the island to the outer frame is cut away at a package end surface after encapsulated in the molded resin body.

### SUMMARY OF INVENTION

### Technical Problem

A thin film resistor network integrated array consisting of metal film is formed on a chip in a semiconductor device, which is surface-mountable such as gull wing type. When a high voltage applying test, which applies a high voltage to the device, because of repeated micro discharges, a carbonized electrically conductive path is possible to be formed on surface of the molded resin package, and then tracking phenomenon, which cause insulation breakdown, is possible to happen.

The invention has been made basing on above-mentioned circumstances. Thus, an object of the invention is to provide a surface-mountable thin film resistor network, which can be prevented from tracking phenomenon occurring in the high voltage applying test.

### Solution to Problem

The surface-mountable thin film resistor network of the invention includes a chip on which a thin-film resistor integrated array has been formed; an island on which the chip is fixed; a plurality of lead terminals extending outward around periphery of the island; wires connecting electrodes of resistors mounted on the chip and the lead terminals; and a molded resin package that encapsulate a portion, which includes the wires;

wherein a hanging lead extending from the island is cut at an end surface of the molded resin package, and an electrical insulation is applied to the cut section of the hanging lead.

In a high voltage applying test, a carbonized electrically conductive path is possible to be formed on a surface of the molded resin package, and then tracking phenomenon, which cause an insulation breakdown, is possible to happen. According to the present invention, because an electrical insulation is applied to the cut section of the hanging lead, which is located at opposite side, a creepage distance for preventing the tracking phenomenon can be secured on the surface of the molded resin package. Then in the high voltage applying test, generation of tracking phenomenon can be suppressed at wide voltage area.

### BRIEF DESCRIPTION OF DRAWINGS

FIG. 1A is a plan view of one section of a lead frame according to an embodiment of the present invention.

FIG. 1B is a plan view at a step, in which connection portions of outer frame, tie bar etc. have been cut away from the lead frame of FIG. 1A.

FIG. 2A is a side view of the package, in which the cut section of the hanging lead is exposed, according to the embodiment of the invention.

FIG. 2B is a side view of the package, in which the electrical insulation is applied to the cut section of the hanging lead, according to the embodiment of the invention.

FIG. 3A is a plan view of the package according to the embodiment of the present invention.

FIG. 3B is a front view of the package according to the embodiment of the present invention.

FIG. 4 is a graph, which illustrates an example of the result of the high voltage applying test.

### DESCRIPTION OF EMBODIMENTS

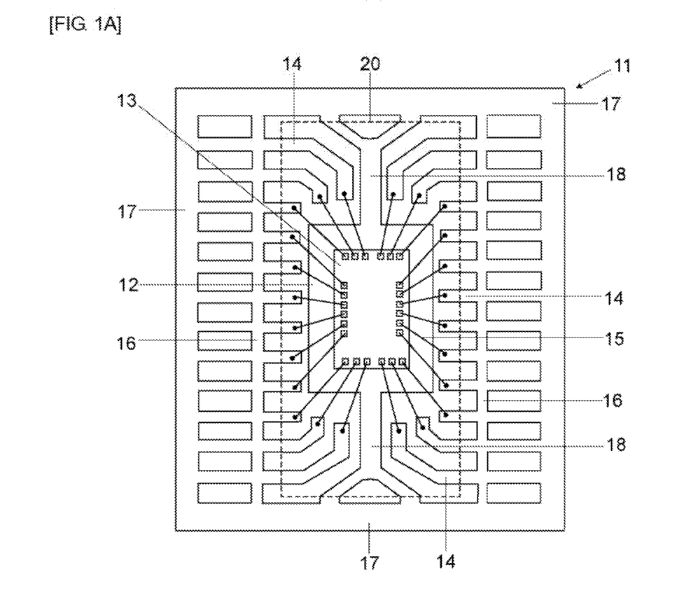

Embodiments of the present invention will be described below with referring to FIG. 1A through FIG. 4. Like or corresponding parts or elements will be denoted and explained by same reference characters throughout views.

FIG. 1A illustrates a manufacturing step of the surface-mountable shin film resistor network. A chip 13 is fixed on an island 12 of a section 11 of a lead frame. A plural of lead terminals 14 is extending outward around periphery of the island 12. An end of lead terminal 14 is connected to a corresponding electrode, that is, an end of a resistor (not shown) by a wire 15. These are encapsulated in a molded resin package 20. The lead frame consists of a thin plate of copper or copper alloy and a lot of sections 11 is continuously formed.

A thin-film (metal film) resistor network integrated array has been formed on the chip 13. A semiconductor silicon chip is used for the chip 13. In the embodiment, 12 pieces of resistor bodies are formed on the chip (not shown). Both ends of 12 resistor bodies, that is, total 24 ends of 12 resistor bodies are connected to total 24 lead terminals 14 by wires 15. The chip 13 is not limited to a semiconductor chip, but also ceramics chip etc. can be used.

A tie bar 16 of one side intersects and connects total 12 lead terminals 14 of one side. Also, total 12 lead terminals of one side are connected to outer frame portion 17. An island 12 on which chip 13 is fixed, is connected to outer frame portion 17 via hanging leads 18. A portion 20 surrounded by dashed line in FIG. 1A and FIG. 1B is encapsulated in molded resin package. The portion 20 encapsulates full of island 12, chip 13 and wires 15, and a part of lead terminals 14 and hanging leads 18.

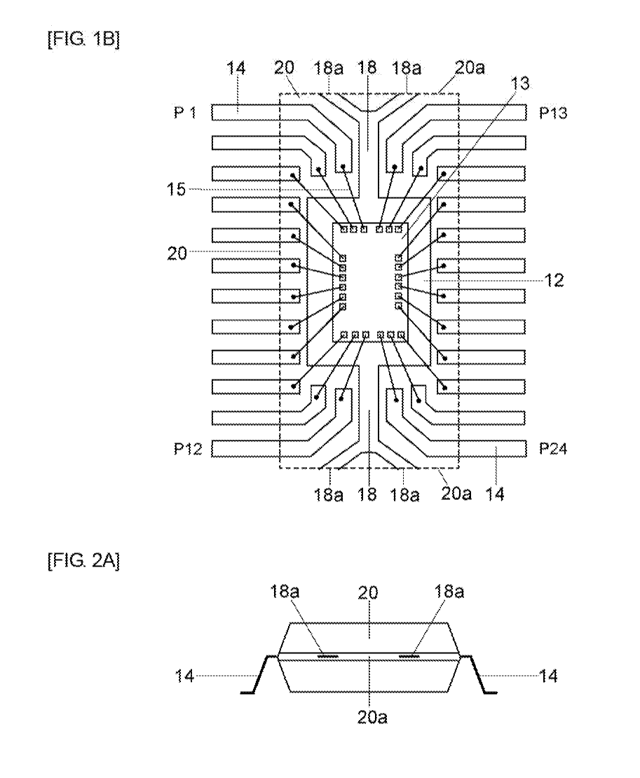

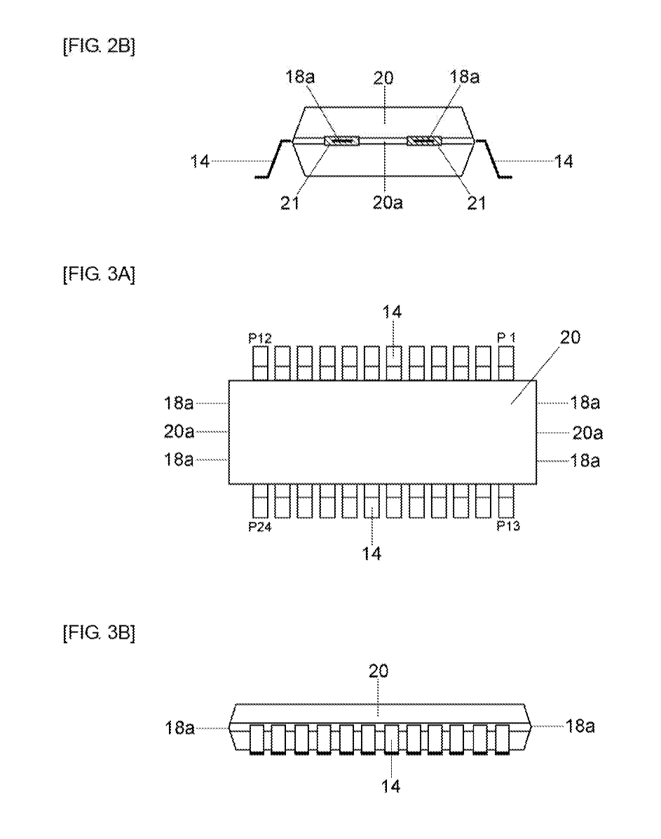

FIG. 1B illustrates a step that unnecessary part of the leadframe have been cut away. That is, unnecessary part includes connection portions of tie bar 17 with lead terminals, where tie bar 17 intersects and connects lead terminals, connection portions of outer frame portion 17 with lead terminals, and connection portions of hanging leads 18 with outer frame portion 17. At the step, a lot of lead terminals 14 is projected from the molded resin package 20. After then, lead terminals 14 are bended, and then, a surface-mountable thin film resistor network (electronic parts) shown in FIGS. 2A-2B and FIGS. 3A-3B has been formed.

As an example, the electronic parts has a size that a length of molded resin package 20 is about 9 mm, a width of the package 20 is about 4 mm, and a height of the package 20 is about 2 mm. The lead terminal 14 has a size that a pitch is 0.635 mm and a width is 0.25 mm. Other than 24 pin-type, there are 20 pin-type, 16 pin-type and so on. Also, these have similar structure and sizes.

The hanging lead 18 is cut at an end surface 20a of length direction of the molded resin package 20. Accordingly, a cut section 18a of the hanging lead 18 is exposed at an end surface 20a of the molded resin package 20 (see FIG. 2A). And, an electrical insulation 21 consisting of an insulative resin film or an insulative inorganic film is applied to the cut section 18A of the hanging lead 18 (see FIG. 2B).

As the material for the insulative inorganic film, a silicon nitride film, a silicon oxide film, or an alumina film etc. can be used. As the material for the insulative resin film, an epoxy system resin film, or a polyimide system resin film, etc. can be used. As the method for applying an electrical insulation, the insulative resin film can be formed by spreading with dispenser or by dipping in liquid-phase resin and drying. Also, the insulative inorganic film can be formed by thermal oxidization method, CVD method, or sputtering method.

That is, the cut section 18a is covered by insulative resin or inorganic film. The electrical insulation 21, which covers the cut section 18a of the hanging lead 18 at an end surface or both end surfaces of the molded resin package, may be an insulating material. Accordingly, the creepage distance of discharging path can be made longer, and higher breakdown voltage can be obtained in high voltage applying test.

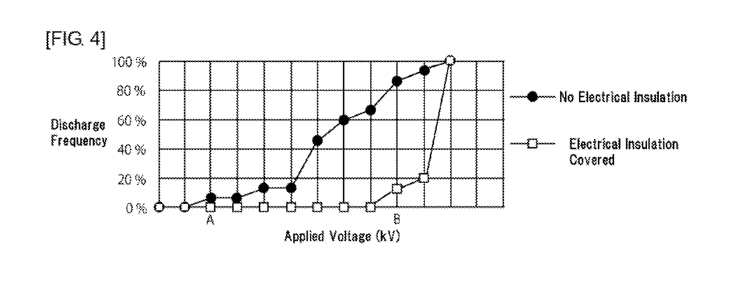

In the high voltage applying test, a high voltage is applied between lead terminals located at opposite side (for example, P1 and P24), then increasing the voltage, and measuring the break down voltage (see FIG. 3A). FIG. 4 illustrates a graph, which shows an example of a result of a high voltage applying test. [symbol] mark (in FIG. 4) shows no electrical insulation 21, that is, the cut section 18a of hanging lead 18 is exposed (see FIG. 2A). □ mark (in FIG. 4) shows the electrical insulation 21 covered, that is, the cut section 18a of hanging lead 18 is covered by the electrical insulation 21 (see FIG. 2B).

FIG. 4 shows that the discharge frequency when increasing applied voltage is compared by the cut section 18a being covered by the electrical insulation 21 or not. When increasing applied voltage, in the case of no electrical insulation 21 on the cut section 18a of the hanging lead 18, the discharge starts at A kV (see FIG. 4). However, when increasing applied voltage, in the case of electrical insulation 21 applied on the cut section 18a of the hanging lead 18, the discharge starts at B kV (see FIG. 4).

According to the result of high voltage applying test, by insulating material such as insulative resin film or insulative inorganic film etc. covering on the cut section 18a of hanging lead 18, the creepage distance of discharge path can be made longer. And, while maintaining same package structure of same size and same function, it is improved in withstand high voltage resistance characteristics.

As shown ( [symbol] in FIG. 4), in case of the cut section 18a of hanging lead 18 exposed (see FIG. 2A), the discharge path is thought to be from lead terminal (P1)→hanging lead 18→island 12→hanging lead 18→lead terminal (P24). (see FIG. 1B)

As shown (□ in FIG. 4), in case of the cut section 18a of hanging lead 18 covered by electric insulation 21 (see FIG. 2B), the discharge path is thought to be from lead terminal (P1)→diagonally on the package 20→via any one of P13-P24→lead terminal (P24). (see FIG. 3A)
Accordingly the creepage distance of discharge path can be fixed to be longer, and higher voltage can be applied corresponding to the creepage distance fixed to be longer.

Then the effect by covering on the cut surface 18a with the electrical insulation 21 enables not only to extend the creepage distance of the discharge path but also to suppress the invasion of moisture etc. into the package. That is, corrosion of wiring can be prevented, which is caused by cell reaction with the moisture or the impurity on the surface of the package and wiring metal.

Although embodiments of the invention have been explained, however the invention is not limited to above embodiments, and various changes and modifications may be made within the scope of the technical concept of the invention.

### INDUSTRIAL APPLICABILITY

The invention can be applicable for the electrical parts such as thin resistor networks, which is encapsulated in molded resin package.

1. A surface-mountable thin film resistor network comprising:
a chip on which a thin film resistor integrated array has been formed;
an island on which the chip is fixed;
a plurality of lead terminals extending outward around periphery of the island;
wires connecting electrodes of resistors mounted on the chip to the lead terminals; and
a molded resin package that encapsulate a portion, which includes the wires;
wherein a hanging lead extending from the island is cut at an end surface of the molded resin package, and an electrical insulation is applied to the cut section of the hanging lead.

2. The thin film resistor network of claim 1, wherein the cut section is covered by an insulative resin.

3. The thin film resistor network of claim 1, wherein the cut section is covered by an insulative inorganic film.

4. A method for manufacturing a surface-mountable thin film resistor network comprising:
preparing a lead frame including an island, a plural of lead terminals extending outward around periphery of the island, an outer frame portion connecting the plural of lead terminals, a hanging lead connecting the island to the outer frame portion, a tie bar intersecting the plural of lead terminals and connecting the plural of lead terminals;
fixing a chip on which a thin film resistor integrated array has been formed on the island;
connecting an electrode of a resistor on the chip and the lead terminal by a wire;
encapsulating a portion including the resistors and the lead terminals connected by the wires in a molded resin package;
cutting off unnecessary part of the lead terminals, which connects to the outer frame portion and the tie bar connection portion, and cutting off the hanging lead at an end surface of the molded resin package, and applying an electrical insulation to a cut section of the hanging lead.
